(19) United States
(12) Patent Application Publication
(10) Pub. No.: US 2014/0322573 A1
(43) Pub. Date: Oct. 30, 2014

(54) BATTERY MONITOR APPARATUS AND BATTERY UNIT

(71) Applicant: Toyota Jidosha Kabushiki Kaisha, Toyota-shi (JP)

(72) Inventors: Norio Nishiwaki, Tajimi-shi (JP); Yuki Tomita, Chiryu-shi (JP)

(21) Appl. No.: 14/255,545

(22) Filed: Apr. 17, 2014

(30) Foreign Application Priority Data
Apr. 24, 2013 (JP) 2013-091797

(51) Int. Cl. G01R 31/36; H01M 10/48

(52) U.S. Cl. CPC G01R 31/3606; H01M 10/482
USPC 429/90; 324/426

(57) ABSTRACT

A battery monitor apparatus includes: a first control unit disposed outside a plurality of battery stacks each including battery cells; a plurality of second control units disposed respectively in the plurality of battery stacks, the second control units determining an output voltage of the battery cells and outputting voltage data representing the determined voltage; and a signal line connecting the plurality of second control units and the first control unit in a daisy chain system, wherein the second control units receive a data signal transmitted from the first control unit and transmit a response signal responding to the data signal, via the signal line, and the first control unit determines that the signal line is disconnected, when the response signal is not received via the signal line within a prescribed time period after transmitting the data signal to the plurality of second control units via the signal line.

### INCORPORATION BY REFERENCE

The disclosure of Japanese Patent Application No. 2013-091797 filed on Apr. 24, 2013 including the specification, drawings and abstract is incorporated herein by reference in its entirety.

### BACKGROUND OF THE INVENTION

1. Field of the Invention

This invention relates to a battery monitor apparatus and a battery unit.

2. Description of Related Art

An apparatus which monitors the states of a plurality of battery assemblies by using a plurality of integrated circuits (ICs) connected mutually by signal lines has been developed. Switching devices are connected to the respective ICs. The ICs receive signals sent from other ICs, and drive the corresponding switching devices.

The switching devices corresponding to the ICs are each driven simultaneously in accordance with an output signal output from one of the ICs (see, for example, Japanese Patent Application Publication No. 2012-161182 (JP 2012-161182 A)).

### SUMMARY OF THE INVENTION

However, in the apparatus for monitoring the states of a plurality of battery assemblies described above, even in a case where any one of the signal lines connecting the ICs is disconnected, there is a possibility that it may not be possible to identify the signal line that is disconnected (referred to as “identifying the disconnection location” below).

This invention provides a battery monitor apparatus and a battery unit which are capable of identifying a disconnection location and implementing a recovery process.

A battery monitor apparatus relating to a first aspect of this invention includes: a first control unit disposed outside a plurality of battery stacks each including battery cells; a plurality of second control units disposed respectively in the plurality of battery stacks, the second control units determining an output voltage of the battery cells and outputting voltage data representing the determined voltage; and a signal line connecting the plurality of second control units and the first control unit in a daisy chain system, wherein the second control units receive a data signal transmitted from the first control unit and transmit a response signal responding to the data signal, via the signal line, and the first control unit determines that the signal line is disconnected, if the response signal is not received via the signal line within a prescribed time period after transmitting the data signal to the plurality of second control units via the signal line.

A battery unit relating to a second aspect of this invention includes a plurality battery stacks including battery cells; and a first control unit disposed outside the battery stacks; a plurality of second control units disposed respectively in the plurality of battery stacks, the second control units determining an output voltage of the battery cells and outputting voltage data representing the determined voltage; and a signal line connecting the plurality of second control units and the first control unit in a daisy chain system, wherein the second control units receive a data signal transmitted from the first control unit and transmit a response signal responding to the data signal, via the signal line, and the first control unit determines that the signal line is disconnected, if the response signal is not received via the signal line within a prescribed time period after transmitting the data signal to the plurality of second control units via the signal line.

A battery monitor apparatus relating to a third aspect of this invention includes: a first control unit disposed outside a plurality of battery stacks each including battery cells; a plurality of second control units disposed respectively in the plurality of battery stacks, the second control units determining an output voltage of the battery cells and outputting voltage data representing the determined voltage; and a communication line connecting the plurality of second control units and the first control unit in a daisy chain system, wherein, upon receiving a data signal transmitted from the first control unit via the communication line, the second control units transfer the data signal via the communication line, and also determine that the communication line is disconnected, when no signal is received via a communication line corresponding to a return path of the daisy chain, within a prescribed time period after transferring the data signal via a communication line corresponding to an outgoing path of the daisy chain.

A battery unit relating to a fourth aspect of this invention includes a plurality of battery stacks including battery cells; and a first control unit disposed outside the battery stacks; a plurality of second control units disposed respectively in the plurality of battery stacks, the second control units determining an output voltage of the battery cells and outputting voltage data representing the determined voltage; and a communication line connecting the plurality of second control units and the first control unit in a daisy chain system, wherein, upon receiving a data signal transmitted from the first control unit via the communication line, the second control units transfer the data signal via the communication line, and also determine that the communication line is disconnected, when no signal is received via a communication line corresponding to a return path of the daisy chain, within a prescribed time period after transferring the data signal via a communication line corresponding to an outgoing path of the daisy chain.

According to the aspects described above, a battery monitor apparatus and a battery unit which are capable of identifying a disconnection location and implementing a recovery process are provided.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a diagram showing a battery monitor apparatus and a battery unit according to a first embodiment of this invention;

FIG. 2A is a set of diagrams showing a battery monitor apparatus according to the first embodiment;

FIG. 2B is a set of diagrams showing a battery monitor apparatus according to the first embodiment;

FIG. 3 is a diagram showing a flow of data between an electric control unit (ECU) and ICs in the battery monitor apparatus according to the first embodiment;

FIG. 4 is a diagram showing a transmission path for voltage data in a battery monitor apparatus according to another example of the first embodiment;

FIG. 5 is a diagram showing a state of data transfer when a disconnection has occurred, in the signal line of the return path between an IC4 and an IC3;

FIG. 6 is a flowchart showing the details of processing by the ECU in a case where a disconnection has occurred in the signal lines of the battery monitor apparatus according to the first embodiment;

FIG. 7 is a diagram showing a data transfer path in a test mode of the battery monitor apparatus according to the first embodiment;

FIG. 8 is a diagram showing a data transfer path in a recovery mode of the battery monitor apparatus according to the first embodiment; and

FIG. 9 is a diagram showing the contents of a control process carried out by the ICs of a battery monitor apparatus according to a second embodiment of this invention.

### DETAILED DESCRIPTION OF EMBODIMENTS

Below, embodiments in which the battery monitor apparatus and the battery unit of this invention are applied will be described.

### First Embodiment

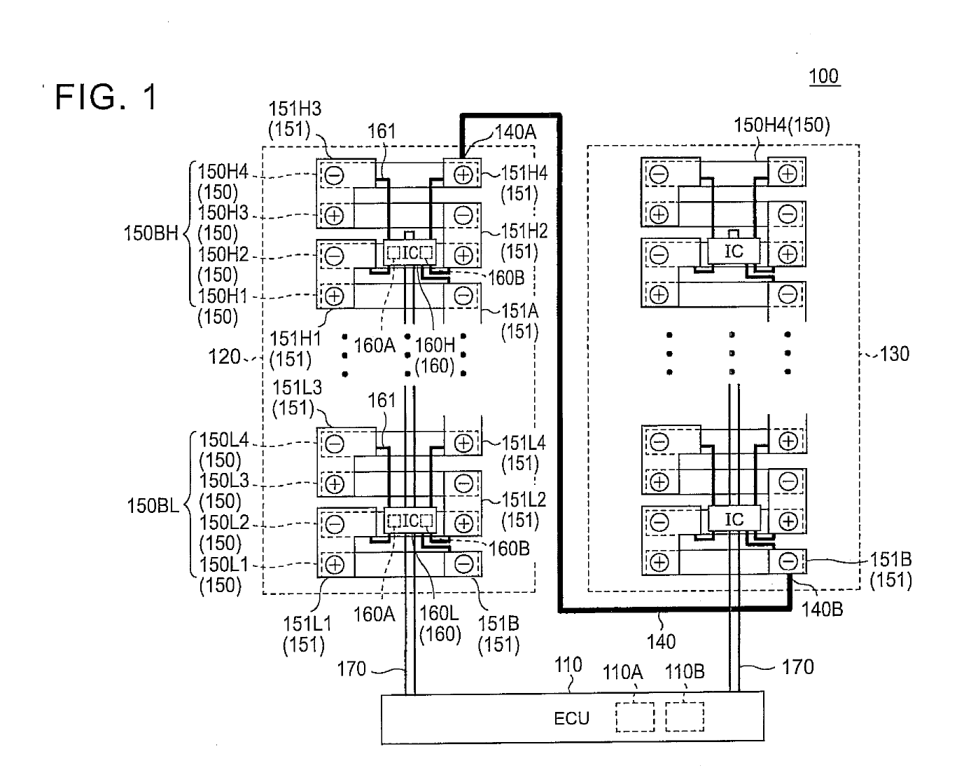

FIG. 1 is a diagram showing a battery monitor apparatus and a battery unit according to the first embodiment.

The battery unit 100 according to the first embodiment includes, as main constituent elements, an ECU 110, and stacks 120 and 130. The stacks 120 and 130 each include a plurality of cells 150 and IC chips 160. The battery monitor apparatus according to the first embodiment is constituted by an ECU 110, and the IC chips 160 included in the stacks 120 and 130.

FIG. 1 shows a schematic plan view of one example of an arrangement of the battery unit 100. The arrangement of the ECU 110 and the stacks 120 and 130 is not limited to the pattern shown in FIG. 1, and may adopt other patterns.

The battery unit 100 is, for example, an apparatus which is used as a power source for outputting electric power to drive a drive apparatus of an electric vehicle (EV). Here, the drive apparatus of an EV is an apparatus which drives a vehicle by driving a travel motor using electric power from the battery unit 100.

The details of the method and composition employed in the EV may be of any kind, provided that the vehicle travels by driving a travel motor using electric power. EVs typically include hybrid vehicles (HV) which have an engine and a travel motor as sources of drive power, and EVs which have only a travel motor as a source of drive power.

The ECU 110 is a control apparatus which implements voltage control processing for the battery unit 100 and the stacks 120 and 130, and is one example of a first control unit. The ECU 110 includes a voltage control unit 110A and a memory 110B. The memory 110B is a non-volatile member from which data can be read and to which data can be written. The ECU 110 may also include an authentication unit which carries out authentication processing of the stacks 120 and 130.

Furthermore, the voltage control processing by the ECU 110 is described below, and here, the description principally concerns the physical configuration of the ECU 110 and the stacks 120 and 130, using FIG. 1.

The stacks 120 and 130 have similar configurations, and are connected in series by a cable 140. Therefore, here, the configuration of the stack 120 is described in detail.

The stack 120 includes a plurality of cells 150 and IC chips 160. FIG. 1 shows eight cells 150H1, 150H2, 150H3, 150H4, 150L1, 150L2, 150L3 and 150L4 which are positioned on either end of a plurality of cells 150 included in the stack 120.

Below, the cells 150H1, 150H2, 150H3, 150H4, 150L1, 150L2, 150L3 and 150L4 are simply called “cells 150”, unless the cells 150 (not illustrated) situated between the cell 150L4 and the cell 150H1 are to be identified in particular.

The positions of the positive terminal and the negative terminal of each cell 150 are indicated by + and − symbols. The plurality of cells 150 included in the stack 120 are connected in series by connecting sections 151.

The cells 150H1, 150H2, 150H3 and 150H4 are connected in series by the connecting sections 151H1, 151H2 and 151H3. Furthermore, the positive terminal (+) of the cell 150H4 is connected to one end 140A of the cable 140 via the connecting section 151H4, and the negative terminal (−) of the cell 150H1 is connected to the connecting section 151A.

Similarly, the cells 150L1, 150L2, 150L3 and 150L4 are connected in series by the connecting sections 151L1, 151L2 and 151L3. Moreover, the positive terminal (+) of the cell 150L4 is connected to the negative terminal (−) of the cell 150 (not illustrated) via a connecting section 151L4, and the negative terminal (−) of the cell 150L1 is connected to the connecting section 151B.

The connecting sections are simply referred to as connecting sections 151, unless the connecting sections 151A, 151H1, 151H2, 151H3 and 151H4 and the connecting sections 151B, 151L1, 151L2, 151L3 and 151L4 are to be identified in particular.

Furthermore, the plurality of cells 150 (not illustrated) positioned between the cell 150L4 and the cell 150H1 are connected in series by connecting sections 151, which are not illustrated. Consequently, the plurality of cells 150 included in the stack 120 are connected in series by the connecting sections 151.

Therefore, of the plurality of cells 150 included in the stack 120, the cell having the highest potential is cell 150H4 and the cell having the lowest potential is cell 150L1.

The cells 150 are, for example, lithium ion secondary batteries, in which the lithium ions in the electrolyte conduct electricity. Here, the lithium ion secondary batteries are called lithium ion batteries. Lithium ion batteries have weak resistance to excessive charging and discharging, and therefore a protective circuit is provided, and excessive charging protection, excessive discharging protection and overcurrent protection are implemented. The excessive charging protection, excessive discharging protection and overcurrent protection are carried out by coordinated operation of the ECU 110 and the IC chips 160.

The IC chips 160 are each composed so as to manage four of the cells 150 included in the stacks 120. FIG. 1 shows an IC chip 160H which is connected to the cells 150H1, 150H2, 150H3 and 150H4, and an IC chip 160L which is connected to the cells 150L1, 150L2, 150L3 and 150L4.

Although not shown in the drawings, in the plurality of cells 150 which are situated between the cell 150L4 and the cell 150H1, one IC chip 160 is connected to four cells 150. In other words, the number of cells 150 included in the stack 120 is a multiple of four, and one IC chip 160 is connected to four cells 150.

Here, the four cells 150 which are connected to one IC chip 160 are called a block 150B. In other words, the cells 150H1, 150H2, 150H3 and 150H4 constitute a block 150BH, and the cells 150L1, 150L2, 150L3 and 150L4 constitute a block 150BL.

Furthermore, the IC chips may be simply referred to as IC chip(s) 160, unless the plurality of IC chips 160 included in the stack 120 (including IC chips 160H and 160L) are to be identified in particular. The IC chips 160 are one example of a second control unit.

The IC chip 160H is connected to the connecting sections 151A, 151H1, 151H2, 151H3 and 151H4 via five cables 161. The IC chip 160H determines the voltage between either end (the end-to-end voltage) of each of the cells 150H1, 150H2, 150H3 and 150H4, via five cables 161.

Similarly, the IC chip 160L is connected to the connecting sections 151B, 151L1, 151L2, 151L3 and 151L4 via five cables 161. The IC chip 160L determines the end-to-end voltage of each of the cells 150L1, 150L2, 150L3 and 150L4, via five cables 161.

Furthermore, the IC chips 160 are connected in a loop to the ECU 110 via signal lines 170. The ECU 110 transmits data, and the like, via the signal lines 170, during voltage control processing.

The signal lines 170 shown in FIG. 1 connect the ECU 110 and the IC chips 160 in a loop fashion. The signal line 170 is turned back at the IC chip 160H to constitute a daisy chain configuration. The signal lines 170 are connected in such a manner that data transmitted from the ECU 110 to the IC chip 160 is transmitted sequentially to the IC chips 160, and then returns to the ECU 110.

More specifically, for example, data which has been transmitted from the ECU 110 to the IC chips 160 and transmitted from the IC chips 160 to the ECU 110 is sent via one of the two signal lines (for example, the right-hand signal line), from the ECU 110, successively via the IC chip 160L, up to the IC chip 160H. Furthermore, the data transmitted from the ECU 110 to the IC chip 160 is sent, via the other of the two signal lines 170 (for example, the left-hand signal line), from the IC chip 160H, successively via the IC chip 160L, to the ECU 110. In this way, the signal lines 170 connect the ECU 110 and the IC chips 160 is a loop fashion to create a daisy chain configuration.

Furthermore, the description given above relates to the stack 120, but the stack 130 has a similar configuration to the stack 120. In FIG. 1, only a portion of the reference symbols relating to the stack 130 are depicted for easier viewing.

The connecting section 151B of the stack 130 is connected to another end 140B of the cable 140. Therefore, the plurality of cells 150 included in the stack 120 and the plurality of cells 150 included in the stack 130 are all connected in series.

Of these cells 150, the cell having the highest potential is the cell 150H4 of the stack 130, and the cell having the lowest potential is the cell 150L1 of the stack 120.

FIG. 1 depicts a state in which two stacks 120 and 130 are connected in series, but it is also possible to connect a larger number of stacks in series, or to provide only one stack (for example, the stack 120 only). Here, a state is depicted in which the stacks 120 and 130 are connected in series, but the stacks 120 and 130 may also be connected in parallel.

In a battery unit 100 of this kind, the IC chips 160 each determine the end-to-end voltages of four cells 150. Data indicating the average value of the end-to-end voltages of the four cells 150 thus determined is sent to the ECU 110.

On the basis of the data indicating the end-to-end voltages sent from the IC chips 160, the ECU 110 adjusts the output voltage of the cells 150 included in the stacks 120 and 130, by discharging cells 150 which have an output voltage equal to or greater than a prescribed voltage, of the cells 150 included in the stacks 120 and 130.

The output voltage can be adjusted by providing a discharge resistance externally to the IC chips 160, and connecting either terminal of a cell 150 having an output voltage equal to or greater than the prescribed volume, to the discharge resistance which is external to the IC chip 160, in such a manner that an output current of the cell 150 passes through the discharge resistance.

The output voltage of a cell 150 has the same meaning as the end-to-end voltage or charging voltage of the cell 150.

In the battery unit 100 according to the first embodiment, in order to adjust the output voltage of the cells 150 included in the stacks 120 and 130, the ECU 110 carries out voltage control processing of the stacks 120 and 130 of the battery unit 100. The voltage control processing is performed by the voltage control unit 110A.

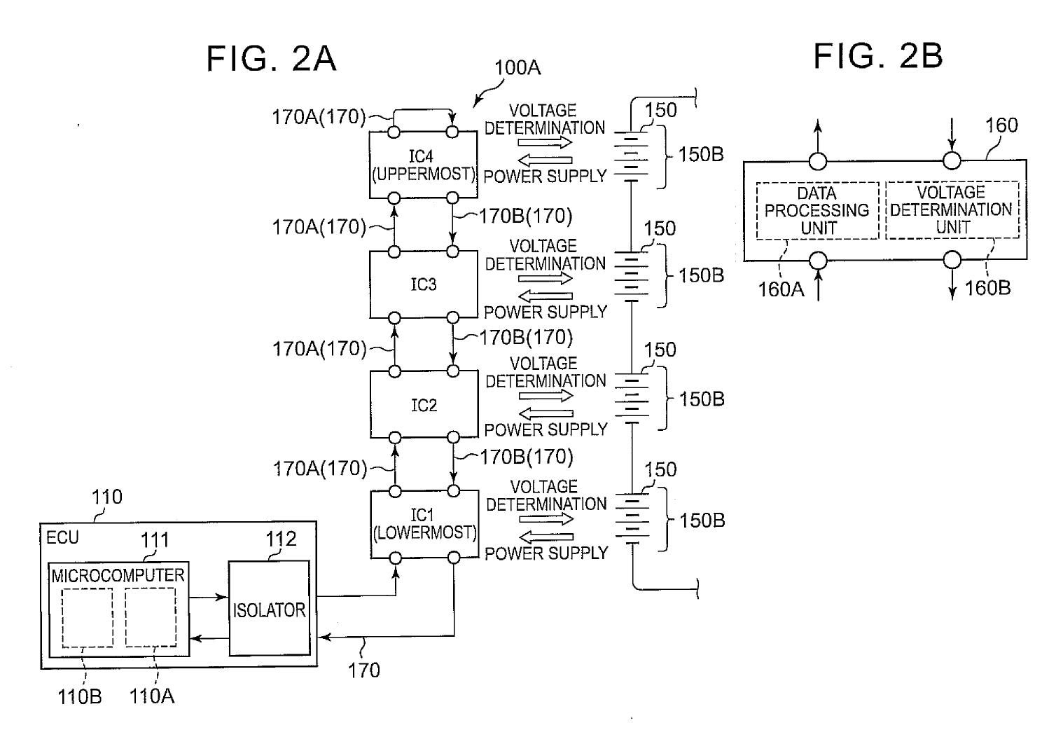

Next, the battery monitor apparatus 100A according to the first embodiment will be described next with reference to FIG. 2A and FIG. 2B.

FIG. 2A and FIG. 2B are a set of diagrams showing a battery monitor apparatus 100A according to the first embodiment, in which FIG. 2A is a diagram showing a schematic view of the battery monitor apparatus 100A, and FIG. 2B is a diagram showing a configuration of an IC chip 160.

FIG. 2A shows ECU 110 and an IC1 to the IC4, as constituent elements of the battery monitor apparatus 100A. The ICs, IC1 to IC4, respectively correspond to the IC chips 160 shown in FIG. 1. Furthermore, FIG. 2A shows a microcomputer 111 and an isolator 112 as constituent elements of the ECU 110. The voltage control unit 110A and the memory 110B are incorporated into the microcomputer 111.

The IC1 to IC4 and the ECU 110 are connected by the signal lines 170 in a network based on a daisy chain system. The communication lines of the network based on the daisy chain system are constituted by an outgoing communication line and a return communication line. Furthermore, in a network based on a daisy chain system, a plurality of control apparatuses are respectively connected to the outgoing communication line and the return communication line. Below, the whole of the network which is connected in a daisy chain system may be referred to simply as a “daisy chain”. Signals are transferred in the respective signal lines 170 in the directions indicated by the arrows.

In FIG. 2A and FIG. 2B, the signal lines 170 are divided into signal lines 170A which correspond to an outgoing path of the daisy chain and signal lines 170B which correspond to a return path of the daisy chain. The signal lines 170A of the outgoing path lead to the IC1 to IC4 from the ECU 110. The signal line 170 which leaves the IC4 and returns to the IC4 is treated as an outgoing signal line 170A.

The signal lines of the return path are signal lines which leave IC4 and lead to the ECU 110.

Here, IC4, which is most distant from the ECU 110, is the uppermost IC chip 160 (see FIG. 1) and IC1 which is nearest to the ECU 110 is the lowermost IC chip (160).

The IC1 to IC4 each have a similar configuration and have four input terminals and four output terminals. In FIG. 2A, the input terminals and output terminals of the IC1 to IC4 are indicated by a circle symbol (0).

In each of the IC1 to IC4, the lower left-side terminal and the upper right-side terminal are input terminals, since the arrows of the signal lines 170 indicate an input direction. Furthermore, in each of the IC1 to IC4, the lower right-side terminal and the upper left-side terminal are output terminals, since the arrows of the signal lines 170 indicate an output direction.

The lower left-side input terminal and the lower right-side output terminal of the lowermost IC1 are connected to the ECU 110 by signal lines 170. The IC1 is able to recognize that it is the lowermost IC chip 160 by, for example, a terminal (not illustrated) being pulled up to a power source VCC.

Furthermore, the upper left-side output terminal and the upper right-side input terminal of the uppermost IC4 are connected in a loop fashion by the signal line 170, in such a manner that IC4 can recognize that it is the uppermost IC chip 160.

The IC1 is connected to the ECU 110 by signal lines 170, and the IC1 to IC4 are connected by signal lines 170.

The signal lines 170 connect the IC1 to IC4 and the ECU 110 in a daisy chain system.

The IC1 to IC4 respectively determine the output voltages of the four cells 150 included in the corresponding block 150B, and find the average value of the four output voltages. Furthermore, the IC1 to IC4 respectively transmit voltage data representing the average value of the four output voltages, to the ECU 110, via the signal lines 170.

Furthermore, as shown in FIG. 2B, the IC chip 160 may have a configuration including a data processing unit 160A and a voltage determination unit 160B, for example. Upon receiving the input of a voltage determination command, the data processing unit 160A causes the voltage determination unit 160B to determine the average value of the output voltages of the four cells 150 included in the block 150B, and generates voltage data on the basis of the average value of the output voltages. Furthermore, the data processing unit 160A transfers the voltage determination command transmitted from the ECU 110 and the voltage data transmitted from other ICs.

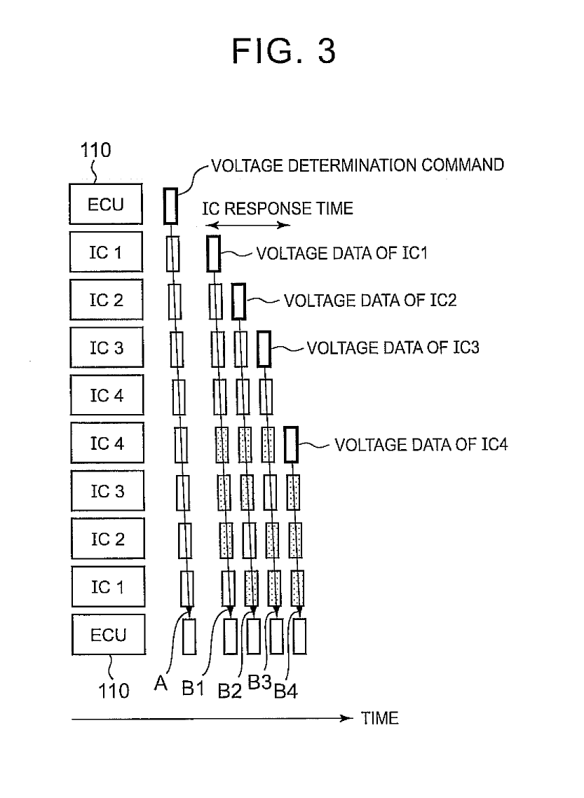

Next, the flow of data between the ECU 110 and the IC1 to IC4 will be described with reference to FIG. 3.

FIG. 3 is a diagram illustrating a flow of data between the ECU 110 and the IC1 to IC4 in the battery monitor apparatus 100A according to the first embodiment. The horizontal axis in FIG. 3 represents a time axis.

In the battery monitor apparatus 100A according to the first embodiment, a voltage determination command is transmitted from the ECU 110 successively to each of the IC1 to IC4, whereupon the IC4, IC3, IC2 and IC1 respectively transmit voltage data representing the average voltage value of the four cells 150 corresponding thereto, to the ECU 110.

In FIG. 3, in order to show the flow of voltage determination commands and voltage data from the top towards the bottom in the vertical direction, a block including the ECU, IC1, IC2, IC3, IC4, IC4, IC3, IC2, IC1 and ECU is depicted. Furthermore, on the right-hand side of each block, the voltage determination command received from each block and the voltage data output from each block are depicted.

The voltage determination commands and voltage data are shifted towards the right-hand side, from the top towards the bottom, in order to represent the passage of time.

As shown in FIG. 3, the voltage determination command is transferred successively from the ECU 110 to the IC1 to IC4, as indicated by the arrow A. The IC1 to IC4 respectively receive the voltage determination commands, successively.

Furthermore, when the voltage determination command reaches the IC4, it is transferred again successively to the IC4, IC3, IC2, IC1 and ECU 110, by the signal line 170 (see FIGS. 1, 2A and 2B), and is thereby returned to the ECU 110. At the start point of arrow A, the voltage determination command output by the ECU 110 to the signal line 170 (see FIGS. 1, 2A and 2B) at this stage is indicated by a bold frame.

The ECU 110 successively transmits, to the IC1 to IC4, a voltage determination command for sending voltage data indicating the average value of the output voltages of the four cells 150, to the ECU 110.

Here, the fact that the ECU 110 successively transmits a voltage determination command to the IC1 to IC4 has the following meaning.

More specifically, the ECU 110 outputs a voltage determination command to the signal lines 170 which constitute the daisy chain, and the voltage determination command is circulated successively to the IC1 to IC4. The IC1 to IC4 each successively transmit the voltage data to the ECU 110, as shown in FIG. 3.

In the first embodiment, between the IC1 to IC4, data or commands are transferred to the upper side form the IC1 towards the IC2, IC3 and IC4, turn back at IC4 and are transferred to the lower side form the IC4 towards IC3, IC2 and IC1, by a daisy chain constituted by signal lines 170.

Therefore, when IC1 has received a voltage determination command from the ECU 110, IC1 transmits voltage data or the voltage determination command to the IC2. Furthermore, upon receiving the voltage data or voltage determination command from the IC1, the IC2 transmits the voltage data or voltage determination command to the IC3. Moreover, upon receiving the voltage data or voltage determination command from the IC2, the IC3 transmits the voltage data or voltage determination command to the IC4.

Furthermore, upon receiving the voltage data or voltage determination command from the IC3, the IC4 turns back the voltage data or voltage determination command and transmits same to the IC3. Moreover, upon receiving the voltage data or voltage determination command from the IC4, the IC3 transmits the voltage data or voltage determination command to the IC2. Furthermore, upon receiving the voltage data or voltage determination command from the IC3, the IC2 transmits the voltage data or voltage determination command to the IC1. Moreover, upon receiving the voltage data or voltage determination command from the IC2, the IC1 transmits the voltage data or voltage determination command to the ECU 110.

From the above, when IC1 receives a voltage determination command and the turn of the IC1 has been reached in the sequence, then the IC1 creates voltage data representing the average value of the output voltages of the corresponding four cells 150 and transmits this voltage data to the IC2 on the upper side.

Furthermore, when IC2 receives a voltage determination command and the turn of the IC2 has been reached in the sequence, then the IC2 creates voltage data representing the average value of the output voltages of the corresponding four cells 150 and transmits this voltage data to the IC3 on the upper side.

Moreover, when the IC3 receives a voltage determination command and the turn of the IC3 has been reached in the sequence, then the IC3 creates voltage data representing the average value of the output voltages of the corresponding four cells 150 and transmits this voltage data to the IC4 on the upper side.

Furthermore, when IC4 receives a voltage determination command and the turn of the IC4 has been reached in the sequence, then the IC4 creates voltage data representing the average value of the output voltages of the corresponding four cells 150 and transmits this voltage data to the IC3.

In FIG. 3, the voltage data output by the IC4, IC3, IC2 and IC1 to the signal lines 170 (see FIGS. 1, 2A and 2B) at the respective stages are indicated by bold frames.

Upon receiving the voltage determination command, IC1, IC2, IC3 and IC4 transmit voltage data, successively from the IC1, towards the IC2, IC3 and IC4 on the upper side thereof, via the signal lines 170, as shown in FIG. 3.

In other words, firstly, the IC1 on the lowermost side transmits voltage data for the four cells 150 corresponding to the IC1, via the signal lines 170, towards the IC2, IC3 and IC4 on the upper side thereof, as indicated by the arrow B1. This voltage data is passed back again from the IC4 and through the IC3, IC2 and IC1 via the signal lines 170, and reaches the ECU 110.

Next, IC2, which is one position to the upper side of the IC1, transmits voltage data for the four cells 150 corresponding to the IC2, via the signal lines 170, towards IC3 and IC4 on the upper side thereof, as indicated by the arrow B2. This voltage data is passed back again from the IC4 and through the IC3, IC2 and IC1 via the signal lines 170, and reaches the ECU 110.

Next, IC3, which is one position to the upper side of the IC2, transmits voltage data for the four cells 150 corresponding to the IC3, via the signal line 170, towards IC4 on the upper side thereof, as indicated by the arrow B3. This voltage data is passed back again from the IC4 and through the IC3, IC2 and IC1 via the signal lines 170, and reaches the ECU 110.

Next, IC4, which is on the uppermost side, transmits voltage data for the four cells 150 corresponding to the IC4, via the signal lines 170, towards IC3, as indicated by the arrow B4. The voltage data is passed via IC3, IC2 and IC1 and reaches the ECU 110.

Furthermore, the IC1 to IC4 acquire the voltage data for other ICs, after the voltage data transferred by the daisy chain constituted by the signal lines 170 has been turned back by IC4.

More specifically, IC4 acquires the voltage data of the IC1 to IC3 indicated by gray in FIG. 3. In other words, IC4 acquires voltage data for the IC1 to IC3 after the daisy chain is turned back at the IC4.

Furthermore, IC3 acquires the voltage data of the IC1, IC2 and IC4 which are indicated by gray in FIG. 3. In other words, IC3 acquires voltage data for the IC1, IC2 and IC4 after the daisy chain is turned back at IC4.

Furthermore, IC2 acquires the voltage data of the IC1, IC3 and IC4 which are indicated by gray in FIG. 3. In other words, IC2 acquires voltage data for the IC1, IC3 and IC4 after the daisy chain is turned back at IC4.

Furthermore, IC1 acquires the voltage data of the IC2, IC3 and IC4 which are indicated by gray in FIG. 3. In other words, IC1 acquires voltage data for the IC2, IC3 and IC4 after the daisy chain is turned back at IC4.

As described above, according to the battery monitor apparatus 100A of the first embodiment, ICs on the upper side can acquire the voltage data of the ICs on the lower side thereof. This is because, as described above, each IC transmits the voltage data of the four cells 150 corresponding thereto, to the upper side via the signal lines 170, successively form the IC1 which is on the lowermost side.

In other words, due to the IC1, IC2 and IC3 outputting voltage data to the upper side via the signal lines 170, the IC1 to IC4 are each able to acquire the voltage data of all of the IC1 to IC4, after the voltage data transferred via the signal lines 170 has been turned back at IC4.

Therefore, each of the IC1 to IC4 can carry out processing, such as averaging the voltage values, by using the voltage data of all of the IC1 to IC4.

Consequently, according to the first embodiment, it is possible to provide a battery monitor apparatus 100A and the battery unit 100 which are capable of implementing voltage control efficiently.

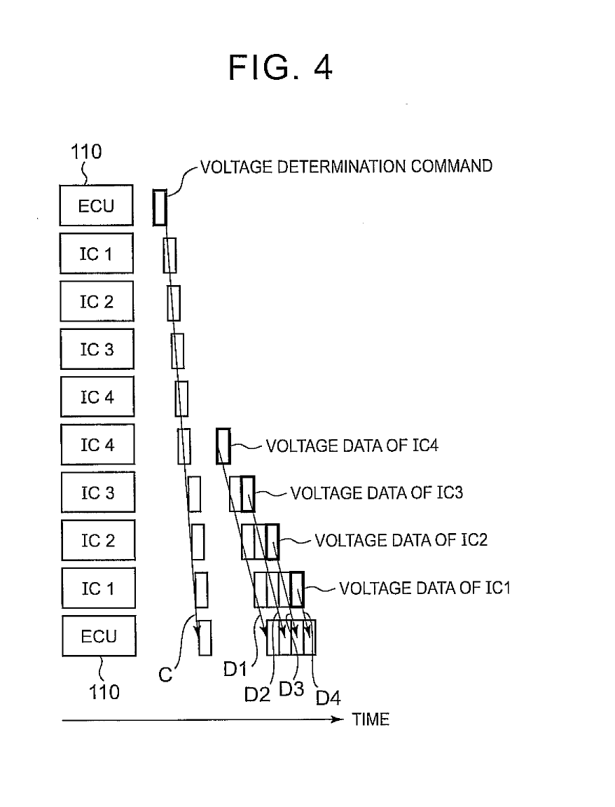

Furthermore, the transmission path of the voltage data in the battery monitor apparatus 100A may be a path such as that shown in FIG. 4.

FIG. 4 is a diagram showing a transmission path for voltage data in a battery monitor apparatus 100A according to another example of the first embodiment.

In FIG. 4, a voltage determination command is transmitted from the ECU 110 successively to each of the IC1 to IC4, whereupon the IC4, IC3, IC2 and IC1 respectively transmit voltage data representing the voltages of the cells 150, to the ECU 110.

As shown in FIG. 4, the voltage determination command is transferred successively from the ECU to IC1 to IC4, as indicated by the arrow C. The IC1 to IC4 respectively receive the voltage determination command, successively.

Furthermore, when the voltage determination command reaches the IC4, it is transferred again successively to the IC4, IC3, IC2, IC1 and ECU 110, by the signal lines 170 (see FIGS. 1, 2A and 2B).

Furthermore, the IC4, IC3, IC2 and IC1 which have received the voltage determination command each respectively transmit voltage data representing the output voltages of the cells 150 they are monitoring, to the ECU 110. In FIG. 4, the voltage data which is output to the signal lines 170 (see FIGS. 1, 2A and 2B) by the IC4, IC3, IC2 and IC1 at the stage in question is indicated by a bold frame.

As a result of this, the voltage data output from the IC4 reaches the ECU 110 via the IC3, IC2 and IC1, as indicated by the arrow D1. Furthermore, the voltage data output from the IC3 reaches the ECU 110 via the IC2 and IC1, as indicated by the arrow D2.

Furthermore, the voltage data output from the IC2 reaches the ECU 110 via the IC1, as indicated by the arrow D3. Furthermore, the voltage data output from the IC1 reaches the ECU 110, as indicated by the arrow D4.

In other words, the IC3 is able to acquire the voltage data of the IC4, IC2 is able to acquire the voltage data of the IC4 and IC3, and IC1 is able to acquire the voltage data of the IC4, IC3 and IC2.

With the data transfer method shown in FIG. 3, it is possible to achieve more efficient voltage control than with the data transfer method shown in FIG. 4, but the data transfer method used in battery monitor apparatus 100A may also be a transfer method such as that shown in FIG. 4.

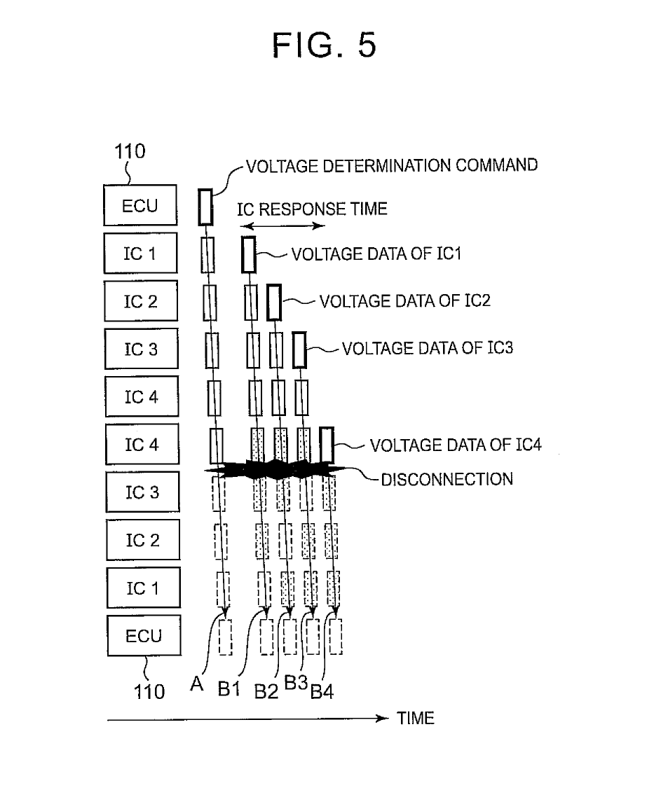

Next, the state of data transfer when a disconnection has occurred in the signal line 170B of the return path between the IC4 and IC3 (see FIG. 2A and FIG. 2B), with the data transfer method shown in FIG. 3, is described with reference to FIG. 5.

FIG. 5 is a diagram showing a state of data transfer when a disconnection has occurred, in the signal line 170B of the return path between the IC4 and IC3 (see FIG. 2A and FIG. 2B).

In FIG. 5, a voltage determination command is transferred from the ECU 110 to the IC1 to IC4 via the signal lines 170 following the arrow A, from the upper side towards the lower side in the diagram.

In accordance with this, the IC1 to IC3 successively transfer their own voltage data to the ICs positioned to the upper side thereof, via the signal lines 170A of the outgoing path. Furthermore, the IC4 outputs the voltage data for the IC4 to the signal line 170B of the return path so as to transfer this voltage data to IC3.

In this case, if a disconnection has occurred in the signal line 170B of the return path between the IC4 and IC3 (see FIG. 2A and FIG. 2B), then as shown in FIG. 5, data cannot be transferred from the IC4 to IC3 by the signal line 170B of the return path, and therefore the voltage determination command indicated by arrow A and the voltage data for the IC1 to IC4 indicated by arrows B1 to B4 cannot be transferred from the IC4 to IC3 via the signal line 170B of the return path.

In FIG. 5, the voltage determination command and the voltage data indicated by the dotted lines show the portion which is not transferred due to the disconnection between the IC4 and IC3 in the signal line 170B of the return path.

When a disconnection of this kind occurs, the voltage determination command does not return to the ECU 110. Furthermore, the voltage data for the IC1 to IC4 does not reach the ECU 110 either.

Moreover, if there is no disconnection in the signal lines 170, then the ECU 110 transmits the voltage determination command to the IC1 to IC4, and the voltage determination command is transferred via the signal lines 170A of the outgoing path, so as to pass through the IC1 to IC4, and is then transferred via the signal lines 170B of the return path, and consequently the time until the ECU 110 receives the voltage determination command is decided by the path length of the signal lines 170 and the processing speed of the IC1 to IC4, and so on.

Therefore, in the first embodiment, the ECU 110 transmits a voltage determination command to the IC1 to IC4, and then determines that a disconnection has occurred in the signal lines 170 if a voltage determination command is not received within the prescribed time period.

Furthermore, if it is determined that a disconnection has occurred in the signal lines 170, then the ECU 110 transmits a test mode command for setting the IC1 to IC4 to a test mode, to the IC1 to IC4, via the signal lines 170.

Furthermore, of the IC1 to IC4, the ICs which have received a test mode command from the ECU 110 via the signal lines 170 provide a response via the signal lines 170B of the return path, when responding to a request from the ECU 110 during the test mode. In other words, in this case, an IC receiving the test mode command does not send a response to the IC on the upper side via the signal lines 170A on the outgoing path, but rather internally switches the transfer destination and sends a response to the IC on the lower side, via the signal line 170B of the return path.

Furthermore, if there is a plurality of ICs, among the IC1 to IC4, which have received the test mode command from the ECU 110 via the signal lines 170, then the plurality of ICs which have received the test mode command respectively send responses via the signal lines 170B of the return path, after mutually different waiting times have elapsed.

Furthermore, the ECU 110 identifies the disconnection location of the signal line 170 on the basis of the responses received from the ICs during the test mode (the ICs which are to the lower side of the disconnection location, among the IC1 to IC4). It is at least possible to identify the ICs, among the IC1 to IC4, between which a disconnection has occurred, in either the signal line 170A of the outgoing path or the signal line 170B of the return path.

Furthermore, after identifying the disconnection location, the ECU 110 transmits a recovery mode command for setting the ICs to the lower side of the disconnection location to a recovery mode. This recovery mode command includes information representing a disconnection location (information indicating the signal line 170 between which IC and which IC where the disconnection has occurred).

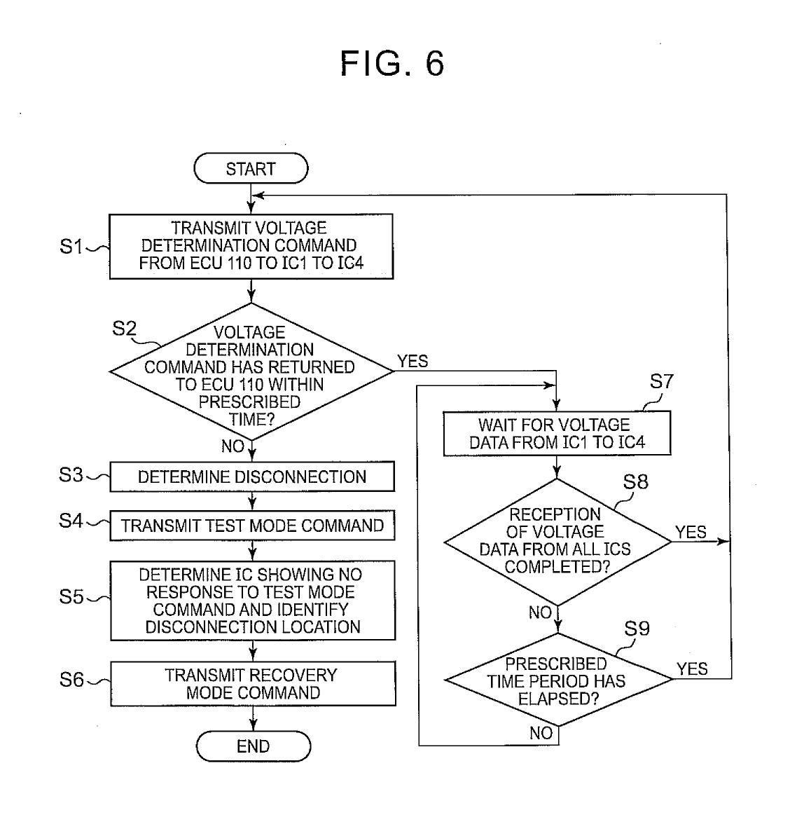

Next, the control processing of the ECU 110 will be described with reference to FIG. 6.

FIG. 6 is a flowchart showing the details of processing by the ECU 110 when a disconnection has occurred in a signal line 170 of the battery monitor apparatus 100A according to the first embodiment.

The ECU 110 starts processing (start). The processing is started, for example, when the ignition is switched on in the vehicle in which the battery monitor apparatus 100A and the battery unit 100 are mounted. It is also possible to execute this processing when the ignition of the vehicle is off.

The ECU 110 transmits a voltage determination command to the IC1 to IC4 (step S1). The processing in step S1 is processing in which the ECU 110 transmits a voltage determination command to the IC1 to IC4.

Furthermore, here, IC1 to IC4 are distinguished by identifiers, and the ECU 110 stores the identifiers of the IC1 to IC4. The IC1 to IC4 associate their own identifier with their voltage data, when transmitting voltage data to the ECU 110.

Furthermore, upon receiving a voltage determination command from the ECU 110, the IC1 to IC4 transfer the voltage determination command to the IC on the upper side thereof, and also generate voltage data.

Consequently, when the voltage determination command is transmitted to IC1 to IC4, from the ECU 110 by the process in step S1, then the IC1 to IC4 receive the voltage determination command successively.

Furthermore, as a result of this, voltage data is transmitted successively to the ECU 110 from the IC1 to IC4 which have received the voltage determination command.

Next, the ECU 110 determines whether or not the voltage determination command which has passed around the signal lines 170 has returned within a prescribed time period. If there is no abnormality in the signal lines 170, then the voltage determination command is transferred to the IC1 to IC4 via the signal lines 170A of the outgoing path, and then passes along the signal lines 170B of the return path and returns to the ECU 110.

In other words, by determining whether or not the voltage determination command has returned at step S2, it is possible to determine the presence or absence of a disconnection in the signal lines 170.

The ECU 110 determines that a disconnection has occurred in the signal lines 170 if the voltage determination command which has passed around the signal lines 170 does not return within the prescribed time period (S2: NO) (Step S3). At this point, it is recognized that a disconnection has occurred at some place in the signal lines 170, but it is still not recognized in which of the signal lines 170 (between which IC and which IC) the disconnection has occurred.

Next, the ECU 110 transmits a test mode command to the IC1 to IC4 (step S4). The test mode command is a command for performing a mode change to set the ICs which are to the lower side of the disconnection location, of the IC1 to IC4, to the test mode.

The ICs which have received the test mode command change the mode to a test mode in order to perform a test response. In the test mode, the ICs transmit a response to the ECU 110 via the signal lines 170B of the return path. This response should be a command which includes an identifier that identifies the IC (any one of the IC1 to IC4).

Next, the ECU 110 determines the IC from which there has been no response to the test mode command, and thereby identifies the disconnection location (step S5).

For example, if there is a response from the IC1 to IC3, but there is no response from the IC4, then the ECU 110 determines that a disconnection has occurred in at least one of the signal lines 170A of the outgoing path between the IC3 and IC4, or the signal lines 170B of the return path.

If a disconnection has occurred in the signal line 170A of the outgoing path between the IC3 and IC4, then the test mode command is not transferred to the IC4. Furthermore, if a disconnection has occurred in the signal line 170B of the return path, between the IC3 and IC4, then the test mode command is transferred to the IC4, but the voltage data of the IC4 is not transferred to the IC3, and consequently, is not transferred to the ECU 110.

Next, the ECU 110 transmits a recovery mode command to the IC1 to IC3 (step S6). The recovery mode is a mode in which a voltage control process is continued by setting the IC nearest to the disconnection location, of the ICs to the lower side of the disconnection location, as the uppermost IC, and the recovery mode command is a command transmitted to the ICs in order to implement the recovery mode.

Furthermore, this recovery mode command includes information representing the disconnection location (information indicating the signal line 170 between which IC and which IC where the disconnection has occurred). More specifically, if a disconnection has occurred between the IC3 and IC4, then information indicating that a disconnection has occurred between the IC3 and IC4 is included in the recovery mode command.

Consequently, if a disconnection occurs in the signal line 170A of the outgoing path, between the IC3 and IC4, then the IC3 recognizes that it is in the uppermost position, and sends a response to the ECU 110. In other words, the IC3 transmits its own voltage data to the ECU 110, without waiting for voltage data to be transferred from the IC4.

The IC4 continues an averaging process of the voltages of the four cells 150 corresponding to the IC4, without transmitting the voltage data.

The ECU 110 terminates the sequence of processing when the processing in step S6 has finished (end).

The ECU 110 may be composed so as to start the sequence of processing again, once a prescribed period of time has passed after completion of the sequence of processing (start).

Furthermore, at step S2, the ECU 110 waits for voltage data to be transferred from the IC1 to IC4, if it is determined that the voltage determination command that has passed around the signal lines 170 has returned within the prescribed time period (S2: YES) (step S7).

Next, the ECU 110 determines whether or not voltage data has been received from all of the ICs (step S8). The ECU 110 determines whether or not the voltage data of all of the ICs is aligned, by comparing the identifiers included in the received voltage data with the identifiers of the ICs held in the ECU 110.

The ECU 110 advances the flow to step S9, if it is determined that the voltage data of all of the ICs is not aligned (S8: NO).

The ECU 110 determines whether or not the prescribed time period has elapsed (step S9). This prescribed time period may be set, for example, to the average time required for the IC1 to IC4 to generate voltage data and transfer the voltage data to the ECU 110, and may be set to an appropriate time in accordance with the usage of the battery monitor apparatus 100A, and the like.

The ECU 110 returns the flow to step S7, if it is determined that the prescribed time period has not elapsed (S9: NO). This is because the ECU 110 continuously waits for the voltage data for the IC1 to IC4.

Furthermore, the ECU 110 returns the flow to step S1, if it is determined that the prescribed time period has elapsed (S9: YES). If the voltage data of the IC1 to IC4 are not aligned within the prescribed time period, then the flow is carried out again from step S1.

Moreover, the ECU 110 returns the flow to step S1 if it is determined that voltage data has been received from all of the ICs in step S8. By carrying out the flow again from step S1, the monitoring of the IC1 to IC4 is repeated.

Voltage control processing by the ECU 110 is carried out as described above.

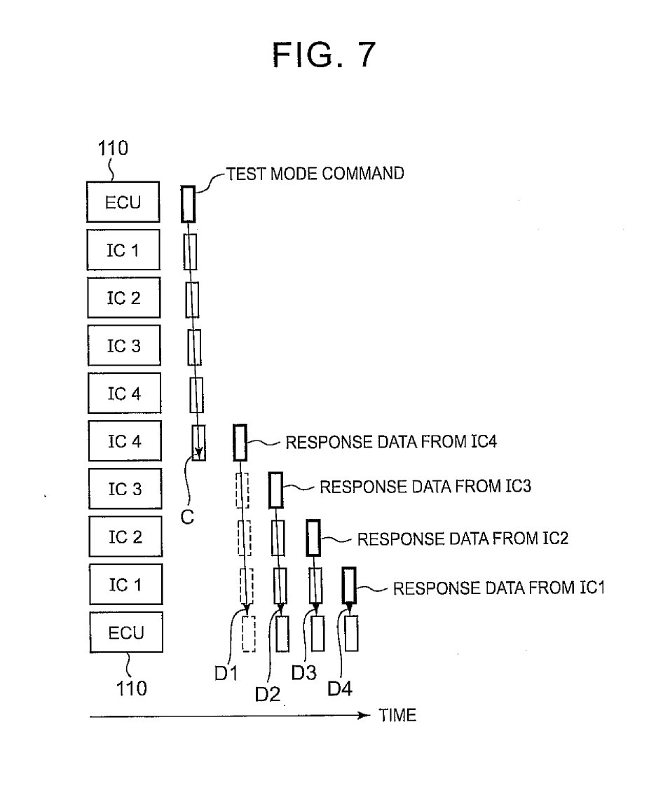

Next, transfer of data in the test mode and the recovery mode will be described with reference to FIG. 7.

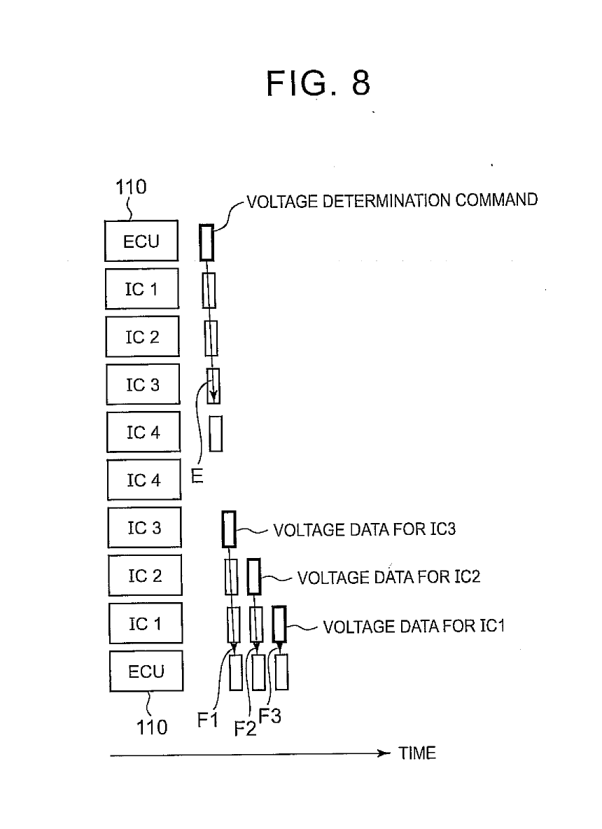

FIGS. 7 and 8 are diagrams showing the data transfer paths in the test mode and recovery mode of the battery monitor apparatus 100A according to the first embodiment. FIG. 7 shows the data transfer path in the test mode, and FIG. 8 is a data transfer path in the recovery mode.

In FIGS. 7 and 8, a disconnection has occurred in the signal line 170B (see FIG. 2A and FIG. 2B) of the return path between the IC3 and IC4.

As shown in FIG. 7, when a test mode command is transmitted from the ECU 110, the test mode command is transferred along the signal lines 170A (see FIG. 2A and FIG. 2B) from the IC1 to IC4, as indicated by arrow C, and is turned back at the IC4.

Here, upon receiving a test mode command, IC1 to IC4 transmit response data to the ECU 110, successively, from the upper side to the lower side. The response data includes the identifiers of each IC. The timings at which the IC4 to IC1 output response data in this order are set to have a broader time interval than the timings at which the voltage data shown in FIG. 3 is output.

In FIG. 7, the response data output by the ICs in test mode is indicated by a bold frame.

The interval at which the response data shown in FIG. 7 is output (in FIG. 7, the interval in the horizontal direction at which the response data indicated by the bold frames occur) is set to be broader than the interval between the timings at which the voltage data is output in FIG. 3. This is in order to avoid overlap of communications between response data transmitted to the ECU 110 in order from the IC4 to IC1.

In this way, the time interval at which the response data is output in order from the IC4 to IC1 should be set in advance in the IC1 to IC4.

Consequently, response data is output in the order: IC4, IC3, IC2 and IC1.

However, in the case shown in FIG. 7, a disconnection has occurred in the signal line 170B (see FIG. 2A and FIG. 2B) of the return path between the IC3 and IC4.

Therefore, the response data transmitted by IC4 is not transferred from the IC3 to the ECU 110. Consequently, FIG. 7 shows the path and a timing at which the response data transmitted by IC4 is originally transferred towards the ECU 110. The response data transmitted to the ECU 110 by the IC4 is transferred to the ECU 110 following the arrow D1, if no disconnection has occurred.

Furthermore, the response data transmitted by IC3 to the ECU 110, is transferred to the ECU 110 via the signal lines 170B of the return path. This transfer is not affected by the disconnection and therefore the response data of the IC3 reaches the ECU 110 via the IC2 and IC1, as indicated by arrow D2.

The response data from the IC3 is transferred to the ECU 110 at a timing that does not overlap with the timing at which the response data from the IC4 is transferred to the ECU 110 in principle if there is no disconnection.

Similarly, the response data transmitted by IC2 to the ECU 110 is transferred to the ECU 110 via the signal lines 170B of the return path. This transfer is not affected by the disconnection and therefore the response data of the IC2 reaches the ECU 110 via the IC1, as indicated by arrow D3.

The response data from the IC2 is transferred to the ECU 110 at a timing that does not overlap with the timing at which the response data from the IC3 is transferred to the ECU 110.

Similarly, the response data transmitted by IC1 to the ECU 110 is transferred to the ECU 110 via the signal lines 170B of the return path. This transfer is not affected by the disconnection and therefore the response data of the IC1 reaches the ECU 110, as indicated by arrow D4.

The response data from the IC1 is transferred to the ECU 110 at a timing that does not overlap with the timing at which the response data from the IC2 is transferred to the ECU 110.

As described above, since the ECU 110 transmits the test mode command to the IC1 to IC4 and receives response data from the IC1 to IC3, then the ECU 110 is able to determine that a disconnection has occurred in the signal line between the IC3 and IC4 (the signal line 170A of the outgoing path or the signal line 170B of the return path). More specifically, the ECU 110 is able to identify the disconnection location.

Furthermore, upon identifying the disconnection connection, the ECU 110 transmits a recovery mode command so as to change the IC1 to IC3 to a recovery mode.

The ECU 110 transmits the recovery mode command to the IC1 to IC3. Information representing the disconnection location is contained in the recovery mode command. Here, information indicating that a disconnection has occurred in the signal line 170 between the IC3 and IC4 is included. Information representing the disconnection location may be stored in a region of several bits in the recovery mode command, for example.

The IC1 to IC3 receive the recovery mode command and changes the mode to recovery mode. On the basis of the recovery mode command, IC3 recognizes that it has become the IC in the uppermost position, due to the fact that a disconnection has occurred between the IC3 and IC4.

In the recovery mode, as shown in FIG. 8, when the ECU 110 transmits a voltage determination command as indicated by arrow E to the IC1 to IC3, then the IC1 to IC3 transmit voltage data to the ECU 110 in the order, the IC3, IC2 and IC1, as indicated by the arrows F1, F2 and F3.

When a disconnection has not occurred, either of the transfer methods shown in FIG. 3 or FIG. 4 may be used, but each of the ICs operating in the recovery mode output voltage data to the signal lines 170B of the return path. In other words, in the recovery mode, the ICs transmit voltage data to the ECU 110 via the signal lines 170B of the return path.

As described above, upon determining that a disconnection has occurred in the signal lines 170, the battery monitor apparatus 100A according to the first embodiment identifies the disconnection location in the test mode, and after identifying the disconnection location, executes a voltage control process using only the ICs to the lower side of the disconnection location (to the near side of ECU 110).

In this way, according to the first embodiment, it is possible to provide a battery monitor apparatus 100A and a battery unit 100 which are capable of identifying a disconnection location and carrying out a recovery process.

### Second Embodiment

The battery monitor apparatus according to a second embodiment employs the voltage data transfer method shown in FIG. 3, as a perquisite condition.

Furthermore, the battery monitor apparatus according to the second embodiment differs from the battery monitor apparatus 100A according to the first embodiment in that the presence or absence of a disconnection in the signal lines 170 is determined by the IC1 to IC4, and if a disconnection occurs, the IC positioned to the uppermost side, of the ICs on the downstream side of the disconnection location, is switched to become the uppermost IC, and a recovery mode is implemented.

The remainder of the composition is similar to the first embodiment, and therefore similar constituent elements are labelled with the same reference numerals and description thereof is omitted here. Furthermore, in the second embodiment, reference is also made to the drawings of the first embodiment, as appropriate.

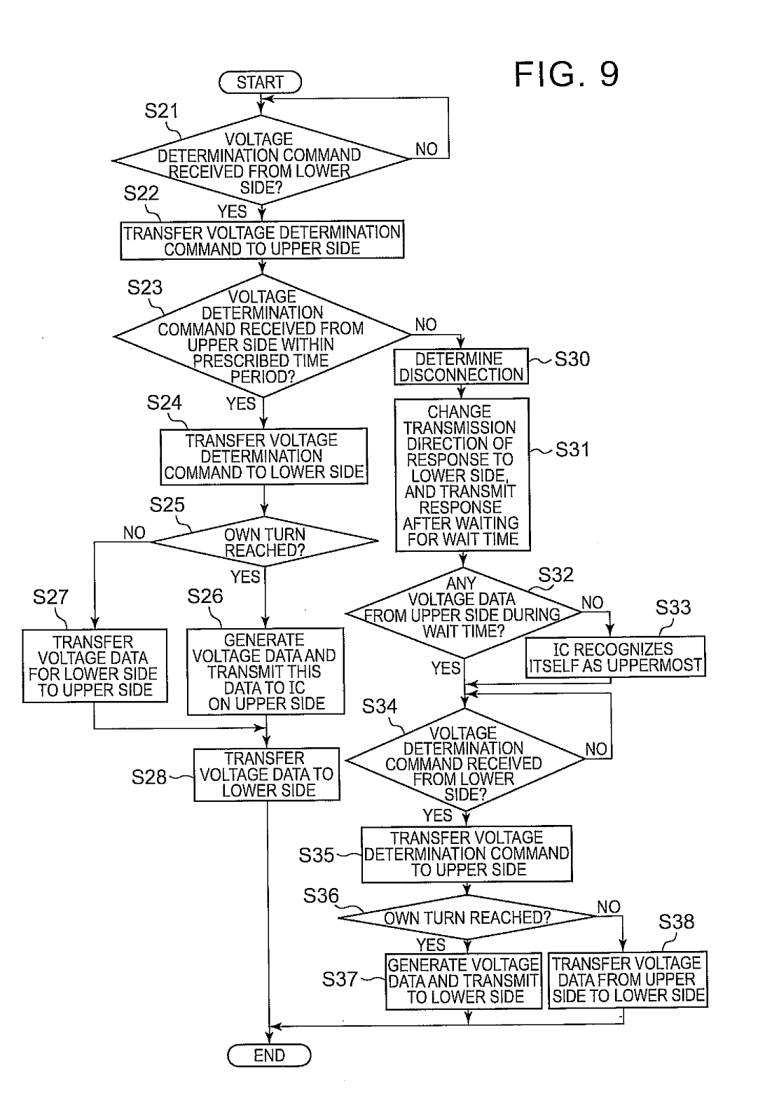

FIG. 9 is a diagram showing the contents of the control process carried out by the ICs of the battery monitor apparatus according to the second embodiment. This control process is processing that is carried out by all of the ICs, IC1 to IC4. Here, the IC1 to IC4 are not distinguished and are simply referred to as “ICs”. The control process is carried out by the data processing unit 160A (see FIG. 2B) in each IC.

The IC starts processing (start). The processing is started, for example, when the ignition is switched on in the vehicle in which the battery monitor apparatus and the battery unit according to the second embodiment are mounted. It is also possible to execute this processing when the ignition of the vehicle is off.

The IC determines whether or not a voltage determination command has been received from the lower side (step S21). This process is carried out repeatedly until a voltage determination command is received from the IC to the lower side.

The IC in the lowermost position, IC1, does not have an IC to the lower side thereof, and therefore in step S21, IC1 may determine whether or not it has received a voltage determination command from the ECU 110.

If an IC determines that a voltage determination command has been received from the lower side, then the IC transfers the voltage determination command to the IC on the upper side (step S22).

Thereupon, the IC determines whether or not a voltage determination command has been received from the upper side within a prescribed time period, after transferring the voltage determination command to the IC on the upper side (step S23). More specifically, after transferring the voltage determination command to the IC on the upper side via the signal line 170A on the outgoing path side, the IC then determines whether or not a voltage determination command has returned from the IC on the upper side via the signal line 170B on the return path side. This process is carried out in order to determine whether or not a disconnection has occurred to the upper side of the IC in question.

If the IC determines that a voltage determination command has been received from the upper side within the prescribed time period (S23: YES), then it transfers the voltage determination command to the lower side (step S24).

Next, each IC determines whether or not its own turn has been reached (step S25). Here, each IC should determine whether or not its own turn has been reached in the following manner, for example.

The IC1 in the lowermost position has no IC positioned to the lower side thereof, and therefore should determine that its own turn has been reached, if IC1 has not yet transmitted voltage data to the upper side.

Furthermore, the IC2 to IC4 should respectively determine that their own turn has been reached, on the basis of whether or not voltage data has been transferred to the upper side by the IC one stage before (one position to the lower side thereof).

Upon determining that its turn has been reached (S25: YES), the IC generates voltage data and transmits this data to the IC on the upper side, via the signal line 170A of the outgoing path (step S26).

In step S26, a composition may be adopted whereby the ICs transmit the voltage data successively after waiting for a prescribed wait time. By adopting this composition, it is possible to manage the timings at which the voltage data is transmitted from the IC1 to IC4, and the voltage data can be transmitted at uniform intervals apart.

Moreover, if an IC determines that its turn has not been reached (S25: NO), then the voltage data transferred from the IC on the lower side via the signal line 170A of the outgoing path is transferred to the IC on the upper side via the signal line 170A of the outgoing path (step S27).

The ICs may also transmit and transfer voltage data successively, without carrying out the determination process from steps S25 to S27.

When the processing in step S26 or S27 is completed, the IC transfers the voltage data transferred from the IC on the upper side, via the signal line 170B of the return path, to the IC on the lower side, via the signal line 170B of the return path (step S28).

Since IC1 is the IC in the lowermost position and does not have an IC positioned to the lower side thereof, then in step S27, IC1 should transfer voltage data that has been transferred from the upper side IC, to the ECU 110.

The flow of the control processing according to steps S21 to S28 above represents normal operations when a disconnection has not occurred in the signal lines 170.

Furthermore, at step S23, if the IC determines that a voltage determination command has not been received from the upper side within a prescribed time period after transferring the voltage determination command to the IC on the upper side (S23: NO), then the IC determines that a disconnection has occurred in the signal lines 170 to the upper side thereof (step S30).

In step S22, if the voltage determination command transferred to the IC on the upper side via the signal line 170A of the outgoing path has not returned to the IC in question via the signal line 170B of the return path, then it is considered that a disconnection has occurred in either the signal lines 170A of the outgoing path or the signal lines 170B of the return path to the upper side of the IC.

Upon detecting a disconnection, the IC changes the response transmission direction towards the lower side, and after waiting for a previously established wait time, transmits a response (step S31). Here, changing the response transmission direction towards the lower side means transmitting the voltage data generated by the IC in question towards the ECU 110 by transmitting to the lower side via the signal line 170B of the return path.

Furthermore, the wait time is different in each of the ICs, IC1 to IC4. This is because the signal lines 170A of the outgoing path and the signal lines 170B of the return path on the upper side of the IC have a different length for each of the IC1 to IC4. Furthermore, for each of the IC1 to IC4, the number of ICs situated to the upper side of the IC in question becomes greater, the lower the position of the IC, and therefore it is necessary to take account of the processing time in the ICs situated to the upper side.

Consequently, the wait times in the IC1 to IC4 should be set respectively by taking account of the length of the signal lines 170A of the outgoing path and the signal lines 170B of the return path to the upper side of the IC in question, and the number of ICs situated to the upper side of the IC in question.

Therefore, the wait time of the IC1 is longest and the wait time of the IC4 is shortest.

The IC determines whether or not voltage data has been transferred from the upper side, during the wait time (step S32). This is in order to determine whether or not an upper-side IC is situated between the IC in question and the disconnection location.

If the IC determines that voltage data has not been transferred from the upper side during the wait time (S32: NO), then the IC recognizes itself to be the IC in the uppermost position (in the recovery mode) (step S33). This is because, in order to implement the recovery mode, the IC nearest to the disconnection location, of the ICs to the lower side of the disconnection location, is set as the uppermost IC in the recovery mode. When the IC has finished the processing in step S33, the IC advances the flow to step S34.

If the IC has determined that voltage data has been transferred from the upper side during the wait time (S32: YES), then the IC advances the flow to step S34.

The IC determines whether or not a voltage determination command has been received from the lower side (step S34). This is in order to transfer a voltage determination command to the upper side, in the recovery mode. The processing in step S34 is repeated until it is determined that a voltage determination command has been received from the lower side.

The IC transfers the voltage determination command received from the lower side, to the upper side (step S35). The voltage determination command transferred to the upper side in this way is not transferred beyond the disconnection location.

The IC determines whether or not its own turn has been reached (step S36). Here, each IC should determine whether or not its turn has been reached in the following manner, for example.

The IC in the uppermost position in the recovery mode determines that its own turn has been reached, if that IC has not yet transferred voltage data to the lower side.

Furthermore, the ICs to the lower side of the IC in the uppermost position in the recovery mode respectively determine that their own turn has been reached, on the basis of whether or not voltage data has been transferred to the lower side by the IC one stage before (one position to the upper side thereof).

Upon determining that its turn has been reached (S36: YES), the IC generates voltage data and transmits this data to the IC on the lower side, via the signal line 170B of the return path (step S37).

If each IC is composed so as to transmit voltage data successively after waiting for a prescribed wait time in step S26, then in step S37, the IC in the uppermost position in the recovery mode may set the wait time from receiving the voltage determination command until transmitting the voltage data, to zero.

Furthermore, if the IC determines that its turn has not been reached (S36: NO), then the IC transfers the voltage data transferred from the IC on the upper side via the signal line 170B of the return path, to the IC on the lower side via the signal line 170B of the return path (step S38).

The ICs may also transmit and transfer voltage data successively, without carrying out the determination process as in steps S36 to S38.

As described above, the processing from steps S30 to S38 which is carried out by the battery monitor apparatus according to the second embodiment corresponds to the test mode and the recovery mode according to the first embodiment.

As described above, when the ICs determine that a disconnection has occurred in the signal lines 170, the battery monitor apparatus of the second embodiment identifies the disconnection location in the test mode, and after identifying the disconnection location, executes a voltage control process using only the ICs to the lower side of the disconnection location (to the near side of ECU 110).

In this way, according to the second embodiment, it is possible to provide a battery monitor apparatus and a battery unit which are capable of identifying a disconnection location and carrying out a recovery process in the ICs.

The ECU 110 carries out disconnection determination and then enters into a fail-safe mode. The ECU 110 may determine the voltage of the stacks 120 and 130, and may also estimate the cell voltage of a section of disconnection occurrence.

For example, if a disconnection occurs in the signal lines 170B of the return path between the IC4 and IC3 (see FIG. 2A and FIG. 2B), then as shown in FIG. 5, a voltage determination command is transferred from the ECU 110 via the signal lines 170 to the IC1 to IC4, following the arrow A, from the upper side towards the lower side in FIG. 5.

In accordance with this, the IC1 to IC3 successively transfer their own voltage data to the ICs positioned to the upper side, thereof, via the signal lines 170A of the outgoing path. Furthermore, IC4 outputs the voltage data for the IC4 to the signal line 170B of the return path so as to transfer this voltage data to the IC3.

In this case, since a disconnection has occurred in the signal line 170B of the return path between the IC4 and IC3 (see FIG. 2A and FIG. 2B), then data cannot be transferred from the IC4 to IC3 by the signal line 170B of the return path, and the voltage determination command indicated by arrow A and the voltage data for the IC1 to IC4 indicated by arrows B1 to B4 cannot be transferred from the IC4 to IC3 via the signal line 170B of the return path.

In FIG. 5, the voltage determination command and the voltage data indicated by the dotted lines indicate the portion which is not transferred due to the disconnection between the IC4 and IC3 in the signal line 170B of the return path.

When a disconnection of this kind occurs, the voltage determination command does not return to the ECU 110. Furthermore, the voltage data for the IC1 to IC4 does not reach the ECU 110 either.

When a disconnection occurs in the signal lines 170B of the return path between the IC4 and IC3 (see FIG. 2A and FIG. 2B), and the ECU 110 transmits a voltage determination command indicated by arrow E to the IC1 to IC3, as shown in FIG. 8, then the IC1 to IC3 transmit voltage data to the ECU 110 in the order, IC3, IC2 and IC1, as indicated by the arrows F1, F2 and F3.

This corresponds to the IC3 recognizing that it is the IC in the uppermost position in the recovery mode and transmitting voltage data to the lower side, whereby IC2 and IC1 successively transmit voltage data to the lower side.

As described above, according to the battery monitor apparatus of the second embodiment, if a disconnection occurs in the signal lines 170, then the IC determines the occurrence of the disconnection, and changes the mode to the recovery mode.

Thereupon, the IC in the uppermost position, of the ICs to the lower side of the disconnection location, recognizes that it is the uppermost IC in the recovery mode, and transmits the voltage data to the ECU 110. Furthermore, the ICs to the lower side of the uppermost IC in the recovery mode follow the operation of the uppermost IC in the recovery mode and transmit voltage data to the ECU 110.

In this way, according to the second embodiment, it is possible to provide a battery monitor apparatus and a battery unit capable of determining the presence or absence of a disconnection in the signal lines 170, on the IC side, and implementing a recovery mode.

A description was given above in relation to a mode in which the stacks 120 and 130 each include four IC chips 160 (IC1 to IC4), but it is also possible to have a greater number of IC chips 160 included in one stack (120 and 130). Furthermore, the number of IC chips 160 included in one stack (120 and 130) may be three or less.

The battery monitor apparatus and battery unit according to exemplary embodiments of the invention have been described above, but this invention is not limited to the embodiments disclosed concretely above, and may be modified or changed variously, without departing from the scope of the claims.

What is claimed is:

1. A battery monitor apparatus comprising:
a first control unit disposed outside a plurality of battery stacks each including battery cells;
a plurality of second control units disposed respectively in the plurality of battery stacks, the second control units determining an output voltage of the battery cells and outputting voltage data representing the determined voltage; and
a signal line connecting the plurality of second control units and the first control unit in a daisy chain system, wherein
the second control units that receive a data signal transmitted from the first control unit and transmit a response signal responding to the data signal, via the signal line, and
the first control unit determines that the signal line is disconnected, when the response signal is not received via the signal line within a prescribed time period after transmitting the data signal to the plurality of second control units via the signal line.

2. The battery monitor apparatus according to claim 1, wherein the first control unit transmits to the plurality of second control units via the signal line a test mode command for setting the second control units to a test mode, when the first control unit determines that the signal line is disconnected.

3. The battery monitor apparatus according to claim 2, wherein, at least one of the plurality of second control units in the test mode makes a response to a request from the first control unit via a return path of the signal line.

4. The battery monitor apparatus according to claim 3, wherein, of the plurality of second control units, when there are a plurality of second control units which have received the test mode command from the first control unit via the signal line, the plurality of the second control units which have received the test mode command respectively make the response via a return path of the signal line, after mutually different wait times have elapsed.

5. The battery monitor apparatus according to claim 3, wherein the first control unit identifies a location of a disconnection in the signal line, on the basis of the response received from the second control unit during the test mode.

6. The battery monitor apparatus according to claim 5, wherein the first control unit transmits a recovery mode command for setting the second control units to a recovery mode, after the disconnection location has been identified.

7. The battery monitor apparatus according to claim 6, wherein the recovery mode command includes information representing the disconnection location.

8. A battery unit comprising:
a plurality of battery stacks including battery cells;
a first control unit disposed outside the battery stacks;
a plurality of second control units disposed respectively in the plurality of battery stacks, the second control units determining an output voltage of the battery cells and outputting voltage data representing the determined voltage; and
a daisy chain connecting the plurality of second control units to the first control unit, wherein
the first control unit determines that a disconnection has occurred in the daisy chain, when there is no response from the plurality of the second control units via the daisy chain within a prescribed time period after transmitting transmission data to the plurality of second control units via the daisy chain.

9. A battery monitor apparatus comprising:
a first control unit disposed outside a plurality of battery stacks each including battery cells;
a plurality of second control units disposed respectively in the plurality of battery stacks, the second control units determining an output voltage of the battery cells and outputting voltage data representing the determined voltage; and
a communication line connecting the plurality of second control units and the first control unit in a daisy chain system, wherein
upon receiving a data signal transmitted from the first control unit via the communication line, the second control units transfer the data signal via the communication line, and also determine that the communication line is disconnected, when no signal is received via a communication line corresponding to a return path of the daisy chain, within a prescribed time period after transferring the data signal via a communication line corresponding to an outgoing path of the daisy chain.

10. The battery monitor apparatus according to claim 9, wherein the second control units which have determined that a disconnection has occurred in the daisy chain make a response to a request from the first control unit, via a return path of the daisy chain, when making the response to the request.

11. The battery monitor apparatus according to claim 10, wherein the second control units which have determined that a disconnection has occurred in the daisy chain make the response via the return path of the daisy chain after mutually different wait times previously assigned to the second control units have elapsed.

12. The battery monitor apparatus according to claim 11, wherein a second control unit determines that a disconnection has occurred in the daisy chain between this second control and another second control unit, which is at more distance from the first control unit than the second control unit, when no response is received from the other second control unit, which is at more distance from the first control unit than the second control unit via the return path of the daisy chain, after the wait time has elapsed.

13. The battery monitor apparatus according to claim 12, wherein the second control unit which has determined that a disconnection has occurred in the daisy chain between this second control unit and another second control unit, which is at more distance from the first control unit, sets a wait time for making a response to the first control unit after making the determination, to zero.

14. A battery unit comprising:
a plurality of battery stacks including battery cells;
a first control unit disposed outside the battery stacks;
a plurality of second control units disposed respectively in the plurality of battery stacks, the second control units determining an output voltage of the battery cells and outputting voltage data representing the determined voltage; and
a communication line connecting the plurality of second control units and the first control unit in a daisy chain system, wherein
upon receiving a data signal transmitted from the first control unit via the communication line, the second control units transfer the data signal via the communication line, and also determine that the communication line is disconnected, when no signal is received via a communication line corresponding to a return path of the daisy chain, within a prescribed time period after transferring the data signal via a communication line corresponding to an outgoing path of the daisy chain.
